(19) United States
(12) Patent Application Publication
(10) Pub. No.: US 2025/0217529 A1
(43) Pub. Date: Jul. 3, 2025

(54) Systems and Methods for Partitioning BIM Models

(71) Applicant: Procore Technologies, Inc., Carpinteria, CA (US)

(72) Inventor: Patrick Lardin, Santa Barbara, CA (US)

(21) Appl. No.: 18/400,907

(22) Filed: Dec. 29, 2023

(51) Int. Cl. G06F 30/13

(52) U.S. Cl. CPC G06F 30/13

(57) ABSTRACT

A computing platform configured to: (i) add a partition for a building information model (BIM) model including BIM data objects to a set of partitions, (ii) for each partition of one or more partitions that each satisfies a threshold, generate a respective partition file by, while the set includes a partition that does not satisfy the threshold: (a) retrieving a partition from the set, (b) if the partition does not satisfy the threshold, (1) determining a center of gravity for the partition, (2) splitting the partition into a first partition and a second partition on opposing sides of the determined center of gravity, and (3) adding the first and second partitions to the set, and (c) if the partition satisfies the threshold, generating a file for the partition, and (iii) generate an index file mapping each of the BIM data objects to a corresponding file.

### BACKGROUND

Building Information Models (BIMs) are used in construction projects to help professionals plan and track the progress of said construction projects. BIM models can hold vast amounts of information related to construction projects, some of which may be encoded into one or more BIM files as BIM data objects that each represents a respective element of a planned real-world structure that is the subject of a construction project. In particular, a given BIM data object includes geometry data that defines the color, size, shape, location, etc. of the given BIM data object when rendered in a BIM model of the planned real-world structure, which may take the form of a three-dimensional (3D) or two-dimensional (2D) model. Given the thousands and even hundreds of thousands of discrete BIM data objects that may correspond to a single BIM model, the amount of geometry data representing the BIM data objects for a given BIM model can be extensive.

### OVERVIEW

In accordance with the above, in one aspect, disclosed herein is a method that involves a computing platform (i) access a set of information encoding geometry data for a plurality of building information model (BIM) data objects for a given BIM model, (ii) add a partition for the given BIM model to a set of partitions, wherein the partition for the given BIM model comprises the plurality of BIM data objects, (iii) for each partition of one or more partitions that each satisfies a partition size threshold, generate a respective partition file by, while the set of partitions includes a partition that does not satisfy the partition size threshold: (a) retrieving a partition from the set of partitions, (b) determining whether the retrieved partition satisfies the partition size threshold, (c) based on determining that the retrieved partition does not satisfy the partition size threshold, (1) determining a center of gravity for the retrieved partition, (2) splitting the retrieved partition into a first partition that falls to a first side of the determined center of gravity for the retrieved partition and a second partition that falls to a second side of the determined center of gravity for the retrieved partition, and (3) adding the first partition and the second partition to the set of partitions, and (d) based on determining that the retrieved partition satisfies the partition size threshold, generating a partition file for the retrieved partition, and (iv) generate a partitions index file mapping each BIM data object of the plurality of BIM data objects to a corresponding generated partition file.

In another aspect, disclosed herein is a client device that includes at least one processor, at least one non-transitory computer-readable medium, and program instructions stored on the at least one non-transitory computer-readable medium that are executable by the at least one processor to cause the client device to carry out the functions disclosed herein, including but not limited to the functions of the foregoing method.

In yet another aspect, disclosed herein is a non-transitory computer-readable medium comprising program instructions that are executable to cause a client device to carry out the functions disclosed herein, including but not limited to the functions of the foregoing method.

One of ordinary skill in the art will appreciate these as well as numerous other aspects in reading the following disclosure.

### BRIEF DESCRIPTION OF THE DRAWINGS

FIG. 1 is an illustration of an example network configuration in which the disclosed technology may be implemented;

FIG. 2 is a flow diagram that illustrates one example of operations of an example process that may be carried out in accordance with the disclosed technology;

FIG. 3 is a flow diagram that illustrates one example of operations of an example process for splitting a BIM model into one or more partitions that may be carried out in accordance with the disclosed technology;

FIG. 4A is a block diagram that depicts a BIM model that includes BIM data objects, in accordance with the disclosed technology;

FIG. 4B is a block diagram that illustrates a table that shows example partition files that may be generated in accordance with the disclosed technology;

FIG. 4C is a block diagram that illustrates a simplified representation of an example partitions index file that may be generated in accordance with the disclosed technology;

FIG. 5 is a block diagram that illustrates an example scene graph that may be generated in accordance with the disclosed technology;

FIG. 6 is a flow diagram that illustrates one example of operations of an example process for presenting a view of a BIM model that may be carried out in accordance with the disclosed technology;

FIG. 7A is a block diagram that illustrates an example viewing frustum in accordance with the disclosed technology;

FIG. 7B is a block diagram that illustrates an example viewing frustum in accordance with the disclosed technology;

FIG. 7C is a block diagram that illustrates an example viewing frustum in accordance with the disclosed technology;

FIG. 8 is a simplified block diagram that illustrates some structural components that may be included in an example back-end computing platform, according to the present disclosure.

FIG. 9 is a simplified block diagram that illustrates some structural components that may be included in an example client device, according to the present disclosure.

### DETAILED DESCRIPTION

The following disclosure makes reference to the accompanying figures and several example embodiments. One of ordinary skill in the art should understand that such references are for the purpose of explanation only and are therefore not meant to be limiting. Part or all of the disclosed systems, devices, and methods may be rearranged, combined, added to, and/or removed in a variety of manners, each of which is contemplated herein.

The present disclosure relates to software technology for partitioning large BIM models into smaller BIM models so that BIM viewing software applications can render large BIM models without running into size limitations.

In line with the previous discussion, BIM models include a plurality of BIM data objects. As used herein, in the context of BIM models used for construction projects, a “BIM data object” refers to a digital representation of a given element of a real-world structure-which may be represented in a three-dimensional (3D) BIM model. A BIM data object may include various types of data. One type of data that may be included in a BIM data object is an BIM data object identifier (object ID), such as an alphanumeric string (e.g., a universally unique identifier (“UUID”) or globally unique identifier (“GUID”)). Another type of data that may be included in a BIM data object may be “geometry” data that provides information about the geometry of BIM data object (and therefore of the real-world element represented by the BIM data object). Specifically, a given BIM data object may have geometry data including (i) a value that defines a color of the given BIM data object, (ii) a value that defines an opacity of the given BIM data object, (iii) a set of vertices of the given BIM data object, and (iv) a set of triangular faces of the given BIM data object, wherein vertices of the set of vertices and triangular faces of the set of triangular faces of the given BIM data object are connected so as to define the location and shape of the given BIM data object. In practice, the geometry data may define the geometry of a BIM data object in various other ways, and there may be various other types of data that may be included in BIM data objects.

Given the thousands and even hundreds of thousands of discrete BIM data objects that may correspond to a single BIM model, the amount of geometry data representing the BIM data objects for a given BIM model can be extensive. As a result, BIM files that encode larger BIM models (i.e., BIM models that include a large amount of geometry data for BIM data objects) can become quite large. In some instances, a BIM viewing software application may be limited in the size of file that may be loaded to render a BIM model. In some cases, a larger BIM file may exceed the limit, resulting in the BIM viewing software application being unable to render the BIM model encoded in the larger BIM file.

More specifically, web-based BIM viewing software applications may only be able to load files smaller than a threshold file size (e.g., a 2 GB file size limit imposed by Javascript language). If a given BIM model is encoded in a BIM file that exceeds the threshold, then a web-based BIM viewing software application may not be able to load the information for the given BIM model from the given BIM file, and as a result may not be able to render the given BIM model.

In view of this limitation, users wishing to view a large BIM model may only be able to do so through BIM viewing software applications that are not bound by such limitations, such as native BIM viewing software applications and the like. However, such applications may not be practical in all situations. For example, mobile devices used by many construction professionals (e.g., smartphones, tablets, etc.) may not have sufficient computing resources to install and run native BIM viewing software applications.

To address these and other problems, disclosed herein is (i) software technology for splitting a large BIM model that may not be rendered by a given BIM viewing software application into one or more partitions and (ii) software technology utilizing the partitions to render portions of the large BIM model. In practice, partitioning a large BIM model into one or more partitions that each includes the geometry data of corresponding BIM data objects of the large BIM model may provide a new level of indirection between a BIM data object and the geometry data for the BIM data object. This, in turn, may enable a BIM viewing software application to load portions of the BIM model (e.g., from one or more of the partitions generated for the given BIM model) on an as-needed basis for rendering the given BIM model. As used herein, the software technology for splitting large BIM models into one or more partitions may be referenced as a “BIM model partitioning tool,” and the software technology for utilizing the partitions generated by the BIM model partitioning tool to render portions of the large BIM model on an as-needed basis may be referenced as a “BIM model rendering tool.”

In practice, the BIM model partitioning tool may be incorporated into a software application that may take any of various forms. For instance, as one possibility, the BIM model partitioning tool may be incorporated into a client-server software application (sometimes referred to as a “web application” or a “Software as a Service (SaaS) application”) comprising client-side software that runs on the client devices and interacts with server-side software installed on a back-end computing platform. As another possibility, the BIM model partitioning tool may be incorporated into a native desktop or mobile application. The BIM model partitioning tool may be incorporated into a software application that takes other forms as well.

In some implementations, the BIM model partitioning tool disclosed herein may be incorporated into a software application that allows a user to view BIM models, referred to herein as a “BIM viewing software application.” In other implementations, the BIM model partitioning tool disclosed herein may be incorporated into a dedicated BIM model partitioning application that partitions larger BIM models into partitions for later use, e.g., by a BIM viewing software application utilizing the BIM model rendering tool. Other implementations are possible as well.

Further, in practice, the BIM model rendering tool may be incorporated into a software application that may take any of various forms. For instance, as one possibility, the BIM model rendering tool may be incorporated into a client-server software application (sometimes referred to as a “web application” or a “Software as a Service (SaaS) application”) comprising client-side software that runs on the client devices and interacts with server-side software installed on a back-end computing platform. As another possibility, the BIM model rendering tool may be incorporated into a native desktop or mobile application. The BIM model rendering tool may be incorporated into a software application that takes other forms as well. Further, in some implementations, the BIM model rendering tool disclosed herein may be incorporated into a BIM viewing software application.

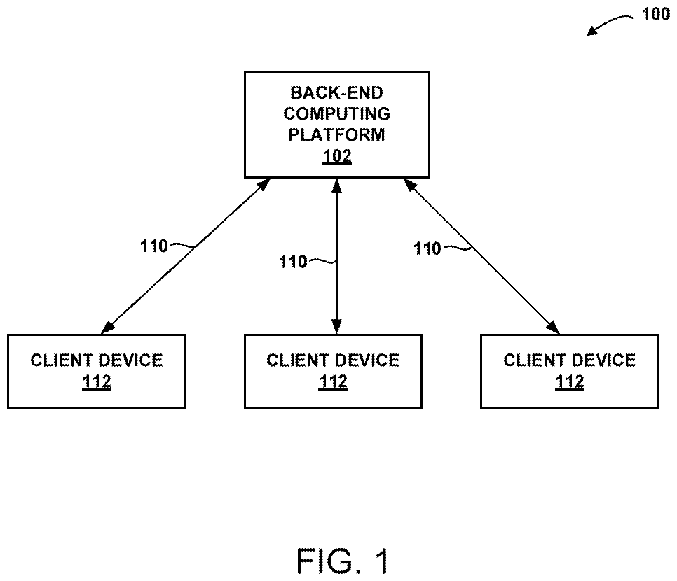

Turning now to the figures, FIG. 1 depicts an example network configuration 100 in which example embodiments of the present disclosure may be implemented. As shown in FIG. 1, the example network configuration 100 includes a back-end computing platform 102 that may be communicatively coupled to one or more the client devices, depicted here, for the sake of discussion, as the client devices 112.

Broadly speaking, the back-end computing platform 102 may comprise one or more computing systems (e.g., one or more servers) that have been provisioned with software for carrying out one or more of the server-side functions disclosed herein. In practice, the one or more computing systems of the back-end computing platform 102 may collectively comprise some set of physical computing resources (e.g., one or more processors, data storage systems, communication interfaces, etc.), which may take any of various forms.

For instance, as one possibility, the back-end computing platform 102 may comprise cloud computing resources supplied by a third-party provider of “on demand” cloud computing resources, such as Amazon Web Services (AWS), Amazon Lambda, Google Cloud, Microsoft Azure, or the like. As another possibility, the back-end computing platform 102 may comprise “on-premises” computing resources of the organization that operates the back-end computing platform 102 (e.g., organization-owned servers). As yet another possibility, the back-end computing platform 102 may comprise a combination of cloud computing resources and on-premises computing resources. Other implementations of the back-end computing platform 102 are possible as well.

Further, in practice, the server-side software may be implemented using any of various software architecture styles, examples of which may include a microservices architecture, a service-oriented architecture, and/or a serverless architecture, among other possibilities, as well as any of various deployment patterns, examples of which may include a container-based deployment pattern, a virtual-machine-based deployment pattern, and/or a Lambda-function-based deployment pattern, among other possibilities.

In turn, the client devices 112 may each be any computing device that is capable of being installed with and running the client-side software disclosed herein, which as noted above may take the form of a client application that runs in a web browser, a native desktop application, or a mobile application, among other possibilities. In this respect, the client devices 112 may each include hardware components such as one or more processors, data storage, communication interfaces, and input/output (I/O) components (or interfaces for connecting thereto), among other possible hardware components, as well as software components such as operating system (OS) software, web browser software, and/or the client-side software disclosed herein, among other possible software components. As representative examples, the client devices 112 may each take the form of a desktop computer, a laptop, a netbook, a tablet, a smartphone, and/or a personal digital assistant (PDA), among other possibilities.

As further depicted in FIG. 1, each of the client devices 112 may be configured to communicate with the back-end computing platform 102 over a respective communication path 110. Each of these communication paths 110 may generally comprise one or more data networks and/or data links, which may take any of various forms. For instance, each respective communication path 110 with the back-end computing platform 102 may include any one or more of point-to-point links, Personal Area Networks (PANs), Local-Area Networks (LANs), Wide-Area Networks (WANs) such as the Internet or cellular networks, and/or cloud networks, where each such data link and/or data network may be wireless, wired, or some combination thereof, and may carry data according to any of various different communication protocols. Additionally, the communication between an example client device 112 and the back-end computing platform 102 may be carried out via an Application Programming Interface (API) provided by the back-end computing platform 102, among other possibilities. Although not shown, the respective communication paths 110 between the client devices 112 and the back-end computing platform 102 may also include one or more intermediate systems, examples of which may include a data aggregation system and host server, among other possibilities. Many other configurations are also possible.

Although not shown in FIG. 1, the back-end computing platform 102 may also be configured to receive data, such as data related to a construction project, from one or more external data sources, such as an external database and/or another back-end computing platform or platforms. Such data sources—and the data output by such data sources—may take various forms.

It should be understood that the example network configuration 100 is one example of a network configuration in which embodiments described herein may be implemented. Numerous other arrangements are possible and contemplated herein. For instance, other network configurations may include additional components not pictured and/or more or fewer of the pictured components.

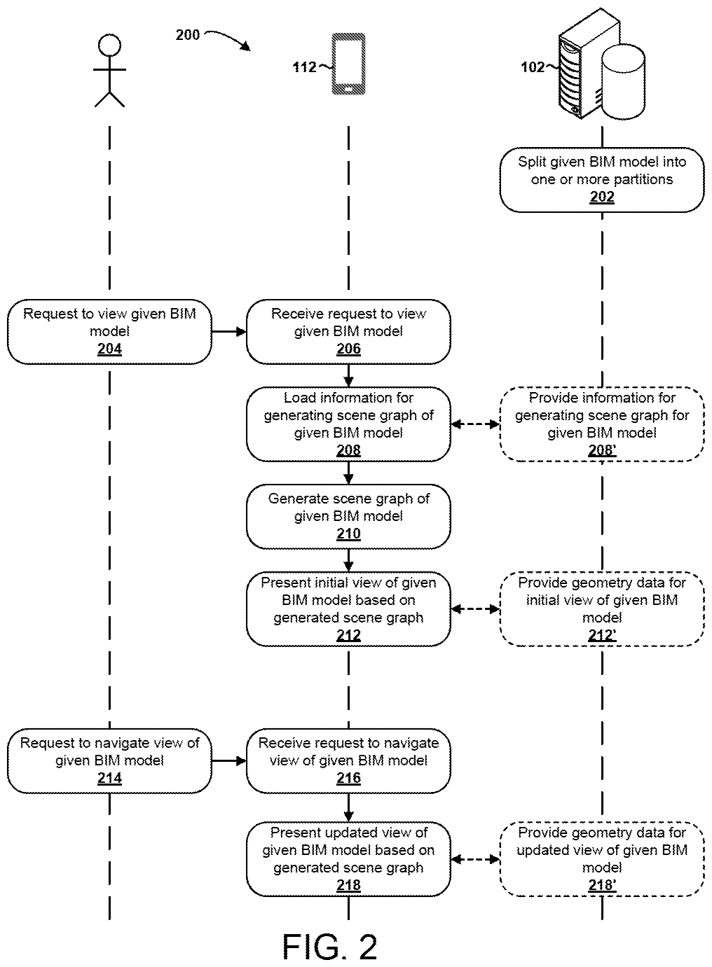

Turning now to FIG. 2, a flow diagram 200 is shown that illustrates example functionality that may be carried out in accordance with the disclosed technology. For purposes of illustration only, the example functionality shown in the flow diagram 200 is described as being carried out within the example network environment of FIG. 1, which as noted above may include a client device 112 and a back-end computing platform 102. It should be understood, however, that the example functionality may be carried out by any of various other devices in any of various other network environments as well. Further, it should be understood that the example functionality is merely described in this manner for the sake of clarity and explanation and that the example functionality may be implemented in various other manners, including the possibility that functions may be added, removed, rearranged into different orders, combined into fewer blocks, and/or separated into additional blocks depending upon the particular embodiment.

In the example illustrated in FIG. 2, it will be assumed that, aside from possibly operations of block 202, as described herein, the example functionality shown in the flow diagram 200 may generally take place after the client device 112 has launched a BIM viewing software application, either as a web application or as a native application.

As shown in FIG. 2, the example functionality may begin at block 202 with the back-end computing platform 102 splitting a given BIM model into one or more partitions.

In line with the previous discussion, certain BIM viewing software applications (e.g., web-based BIM viewing software applications) may not be able to load BIM models encoded in one or more BIM files that exceed a threshold size. Splitting these larger BIM models into one or more partitions may enable these BIM viewing software applications to render large BIM models that are encoded in one or more BIM files that exceed a threshold size. Specifically, by splitting the given BIM model into one or more partitions, the back-end computing platform 102 may enable BIM viewing software applications utilizing the BIM model rendering tool to load portions of the information needed to render the given BIM model on an as-needed basis.

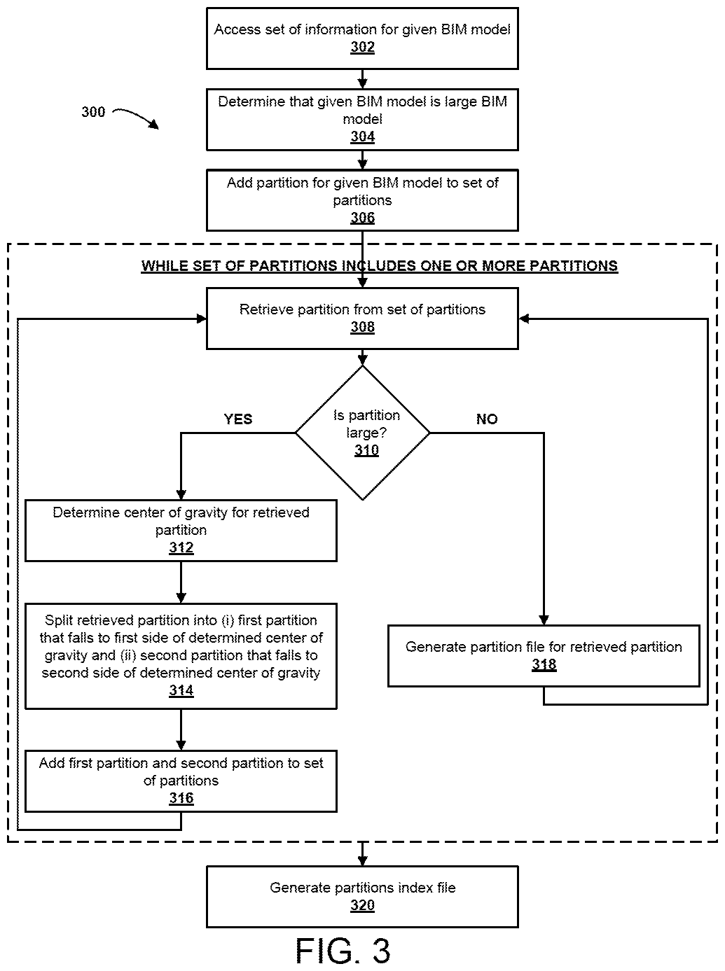

As used herein, a “partition” refers to a finite portion of space within a given BIM model (e.g., defined by a bounding box) and includes BIM data objects that are located within the partition, as described in greater detail below. The details regarding how the back-end computing platform 102 splits the given BIM model into two or more partitions is described in FIG. 3.

As shown, FIG. 3 includes a flow diagram 300 that illustrates example functionality that may be performed by the back-end computing platform 102 to split a given BIM model into one or more partitions. Thereafter, BIM viewing software applications can load partitions from the given BIM model on an as-needed basis without running into a threshold file size limit for the given BIM file.

At block 302, the back-end computing platform 102 may begin by accessing a set of information (e.g., from one or more BIM files) that encodes the given BIM model, including information encoding the plurality of BIM data objects of the given BIM model. In practice, the set of information for the given BIM model may be stored in one or more BIM files.

As one possibility, the set of information for the given BIM model may be stored in a given BIM file, and the back-end computing platform 102 may access the set of information from the given BIM file. As another possibility, the set of information for the given BIM model may be stored in more than one BIM file. For instance, one BIM file may include one type of construction-related information for the given BIM model (e.g., information for plumbing systems of the given BIM model) while another BIM file may include a different type of construction-related information for the given BIM model (e.g., information for HVAC systems of the given BIM model). When the overall set of information for the given BIM model is stored in more than one BIM file, the back-end computing platform 102 may access the overall set of information by accessing each of the BIM files that includes information for the given BIM model. Various other possibilities may also exist.

Further, the back-end computing platform 102 may access the set of information from the one or more BIM files in various ways. In one implementation, a BIM file storing the set of information may be stored by the back-end computing platform 102, and the back-end computing platform 102 may access the set of information from the BIM file by retrieving the set of information from storage of the back-end computing platform 102. In another implementation, a BIM file storing the set of information may be stored externally, and the back-end computing platform 102 may access the set of information from the BIM file by requesting the set of information from an external computing system storing the BIM file.

In implementations where various portions of the set of information are stored by different BIM files, some of the BIM files storing respective portions of the set of information may be stored by the back-end computing platform 102, whereas others of the BIM files storing respective portions of the set of information may be stored externally. In such implementations, the back-end computing platform 102 may retrieve portions of the set of information that are stored in BIM files stored by the back-end computing platform 102 from the storage of the back-end computing platform 102, and may retrieve portions of the set of information that are stored in BIM files stored remotely by requesting said portions of the set of information from an external computing system storing said BIM files. Various other implementations are also possible.

Further, in practice, the back-end computing platform 102 may access the set of information for the given BIM model at various times, and possibly in response to various triggers.

According to one implementation, the back-end computing platform 102 may access the set of information for the given BIM model in response to a user request, such as the user request shown in block 204, as described in greater detail below. According to another implementation, the back-end computing platform 102 may access the set of information for the given BIM model when the given BIM model is created and/or updated. The back-end computing platform 102 may access the set of information for the given BIM model at various other times as well, and possibly in response to various other triggers.

At block 304, the back-end computing platform 102 may determine that the given BIM model is a large BIM model. The back-end computing platform 102 may determine that the given BIM model is a large BIM model if the set of information (or possibly portion of the set of information) of a given BIM file exceeds a threshold size.

The threshold size relates to the maximum size of information that may be loaded from a given BIM file by a given BIM viewing software application (e.g., web-based BIM viewing software application) for rendering the given BIM model. In practice, this threshold size may take any of various possible forms. As one example, BIM viewing software applications running a browser implementation of the Javascript language are limited by a threshold file size of 2 GB. Various other examples may also exist.

To determine whether the given BIM model is a large BIM model, the back-end computing platform 102 may, for a given BIM file that includes information for the given BIM model (e.g., geometry data for BIM data objects of the given BIM model), (i) determine the total size of information loaded from the given BIM file and then (ii) compare the total size of information loaded from the given BIM file to the threshold size to determine whether the total size of information loaded from the given BIM file exceeds the threshold size. To determine the total size of information loaded from the given BIM file, the back-end computing platform 102 may count the total byte size of the geometry data of each BIM data object encoded in the information loaded from the given BIM file. As the set of vertices and the set of triangular faces may make up a significant portion of the geometry data for any given BIM data object, the back-end computing platform 102 may accomplish this by counting the total byte size of the set of vertices and the set of triangular faces for each BIM data object encoded in the information loaded from the given BIM file.

After determining the total size of the information loaded by the given BIM file, the back-end computing platform 102 may compare the total size with the threshold size to determine whether the total size of information loaded from the given BIM file exceeds the threshold size. If so, then the back-end computing platform 102 may determine that the given BIM model is a large BIM model. If not, then the back-end computing platform 102 may determine that the given BIM model is not a large BIM model.

If the back-end computing platform 102 determines that the given BIM model is a large BIM model, then the back-end computing platform 102 may continue performing operations of the example functionality of the flow diagram 300, e.g., by proceeding to block 306. However, if the back-end computing platform 102 determines that the given BIM model is not a large BIM model, then the back-end computing platform 102 may cease performing further operations of the example functionality. In practice, the back-end computing platform 102 may then optionally begin performing the operations of the example functionality for another BIM model, e.g., in implementations where the back-end computing platform 102 is configured to perform operations of the example functionality for multiple BIM models stored by the back-end computing platform 102 or otherwise accessible to the back-end computing platform 102.

In line with the previous discussion, once the back-end computing platform 102 has determined that the given BIM model is a large BIM model, the back-end computing platform 102 may then split the given BIM model into two or more partitions. In practice, the back-end computing platform 102 may split the given BIM model into two or more partitions in various ways. The remaining operations of the example flow diagram 300 describe one manner in which the back-end computing platform 102 may split the given BIM model into one or more partitions, although it should be understood that the back-end computing platform 102 may split the given BIM model into one or more partitions in various other ways as well.

At block 306, the back-end computing platform 102 may add a partition for the given BIM model to a set of partitions for the given BIM model. In line with the previous discussion, a partition may define (e.g., via a bounding box) a finite volume of space in a BIM model. As a starting point, the partition for the given BIM model may define the entire volume of space for the given BIM model and may include each BIM data object of the given BIM model.

The set of partitions for the given BIM model may take various forms. As one example, the set of partitions may be a data structure that employs a first-in-last-out (FILO) or last-in-first-out (LIFO) protocol, such as a stack. However, the set of partitions may take other forms as well.

Further yet, the set of partitions may include a dynamic number of partitions. For example, before adding the initial partition for the given BIM model to the set of partitions, the set of partitions may be empty, and after adding the initial partition for the given BIM model to the set of partitions, the set of partitions may include only the initial partition. As described in greater detail herein, partitions may be added or removed from the set of partitions as part of the process of splitting the given BIM model into one or more partitions. However, it should be understood that following examples represent one possible manner of utilizing a set of partitions to split the given BIM model into one or more partitions, and other possibilities may also exist.

Blocks 308-318 are described as being iteratively performed to generate one or more partition files for one or more partitions that each satisfies a partition size threshold. For instance, operations of blocks 308-318 may be iteratively performed to (i) remove a partition from the set of partitions when it satisfies a partition size threshold and (ii) generate a partition file for the partition that is removed from the set of partitions. As a result, the operations of blocks 308-318 may be iteratively performed while the set of partitions includes one or more partitions, (i.e., until the set of partitions is empty).

It should be noted that the partition size threshold may be different than the threshold file size that can be loaded by a given BIM viewing software application for the given BIM model. Rather, the partition size threshold may instead define a maximum size for partitions that the back-end computing platform 102 may generate via the example functionality of the flow diagram 300.

The partition size threshold may take various forms and may generally be smaller than the threshold file size that can be loaded by a given BIM viewing software application for the given BIM model. For instance, the threshold file size for the given BIM viewing software application may be 2 GB, whereas the partition size threshold may be 50 MB. In this way, multiple partitions may be loaded at once by a BIM viewing software application, during a rendering phase, without exceeding the maximum file size. Various other examples may also exist.

Further, the partition size threshold may be defined in various ways. As one possibility, the partition size threshold may be user-defined. For instance, a user of the BIM model partitioning tool may input the partition size threshold via a client device 112. As another possibility, the back-end computing platform 102 may automatically determine the partition size threshold.

In some circumstances, the geometry data for a given BIM data object of the given BIM model may be significantly larger than the geometry data for other BIM data objects of the given BIM model. For instance, a BIM data object of the given BIM model representing a large, winding pipe may include a large amount of geometry data, relative to the amount of geometry data included in other BIM data objects of the given BIM model. In such circumstances, the back-end computing platform 102 may be configured to exclude the given BIM data object from the partition size threshold, and may instead, as explained in greater detail below, generate a special partition that only includes the given BIM data object. Various other possibilities may also exist.

At block 308, the back-end computing platform 102 may retrieve a partition from the set of partitions. In the first instance of the back-end computing platform 102 performing operations of the block 308, the retrieved partition may be the initial partition for the given BIM model (i.e., the partition defining the entire space of the given BIM model). However, as described in greater detail below, other instances of the back-end computing platform 102 performing operations of the block 308 may include the back-end computing platform 102 retrieving other partitions that may be added to the set of partitions.

In practice, the act of retrieving a given partition from the set of partitions may remove the given partition from the set of partitions. Further, if the back-end computing platform 102 is unable to retrieve a partition from the given set of partitions (i.e., if the set of partitions is empty when the back-end computing platform 102 attempts to perform operations of block 308), then the back-end computing platform 102 may cease performing operations of blocks 308-318 and jump to block 320. As described in greater detail herein, partitions are removed from the set of partitions when they satisfy the partition size threshold, and so repeating operations of the example functionality of the flow diagram 300 until the set of partitions is empty may indicate that the back-end computing platform 102 has completed splitting the given BIM model into two or more partitions that each satisfies the partition size threshold.

At block 310, the back-end computing platform 102 may determine whether the retrieved partition is a large partition. To determine whether the retrieved partition is a large partition, the back-end computing platform 102 may (i) determine the total size of the retrieved partition and then (ii) compare the total size of the retrieved partition to the partition size threshold to determine whether the total size of the retrieved partition exceeds the partition size threshold. To determine the total size of the retrieved partition, the back-end computing platform 102 may count total byte size of the geometry data of each BIM data object of the retrieved partition. In line with the previous discussion, the back-end computing platform 102 may accomplish this by counting the total byte size of the set of vertices and the set of triangular faces for each BIM data object of the retrieved partition. The back-end computing platform 102 may determine the total byte size of the geometry data in various other ways as well.

It should be noted that in the first iteration of the back-end computing platform 102 performing operations of block 310, the retrieved partition may be the partition that defines the entire space of the given BIM model, and the back-end computing platform 102 may already know that the retrieved partition is a large partition by virtue of the given BIM model, as determined at block 304. In such implementations, the back-end computing platform 102 may determine that the retrieved partition is a large partition based on it being the partition that defines the entire space of the given BIM model. Alternatively, the back-end computing platform 102 may skip the operations at block 310 for the first iteration of the loop shown in FIG. 3.

After determining the total size of the retrieved partition, the back-end computing platform 102 may compare the total size with the partition size threshold to determine whether the total size of the retrieved partition exceeds the partition size threshold. If so, then the back-end computing platform 102 may determine that the retrieved partition is a large partition and may proceed to block 312. If not, then the back-end computing platform 102 may determine that the retrieved partition is not a large partition and may proceed to block 318.

In line with the discussion above, the back-end computing platform 102 may proceed to block 312 if the back-end computing platform 102 determines that the retrieved partition is a large partition at block 310. At block 312, the back-end computing platform 102 may determine a center of gravity for the retrieved partition. As used herein, the “center of gravity” for a given partition may refer to a 2-dimensional plane within the given partition that is positioned such that the “weight” of geometry data to one side of the 2-dimensional plane is approximately equal to the “weight” of geometry data to the other side of the 2-dimensional plane. Further, as used herein, the “weight” of geometry data may refer to the quantity of geometry data (e.g., vertices, faces, etc.) that exists in a given location. To illustrate with an example, the geometry data for a first BIM data object at a first location in a partition may include a large set of vertices and a large set of triangular faces, and the geometry data for a second BIM data object at a second location in the partition may include a small set of vertices and a small set of triangular faces. In this example, the geometry data for the first BIM data object may have more “weight” than the geometry data for the second BIM data object, thereby pulling the center of gravity of the partition closer to the first object. Further, it should be noted that the weight of a given BIM data object need not correspond to the physical size of the corresponding real-world object that it represents. Rather, a BIM data object's weight corresponds more closely to the amount of data needed to represent the object. For instance, a relatively small but highly detailed BIM data object may have a greater weight than a relatively large object that can be represented with fewer vertices and faces.

As may be appreciated, the retrieved partition may include many BIM data objects, and the back-end computing platform 102 may determine the center of gravity for the retrieved partition based on the respective weight of each BIM data object of the retrieved partition. For the reasons noted above, this may result in portions of a BIM model that include densely packed and/or highly detailed BIM data objects being divided into more partitions than other portions of a BIM model that include more sparse and/or less detailed BIM data objects.

In practice, the back-end computing platform 102 may determine an orientation of the center of gravity of the retrieved partition. As one possibility, the back-end computing platform 102 may orient the center of gravity of the retrieved partition along a given dimension of the retrieved partition (as defined by a bounding box of the retrieved partition), such as the longest dimension of the retrieved partition. As a result, the center of gravity of the retrieved partition may be represented by a plane that runs perpendicular to the given dimension of the retrieved partition. Various other possibilities may also exist.

At block 314, the back-end computing platform 102 may split the retrieved partition along the determined center of gravity. This may result in the back-end computing platform 102 splitting the retrieved partition into (i) a first partition that falls to a first side of the determined center of gravity of the retrieved partition and (ii) a second partition that falls to a second side of the determined center of gravity of the retrieved partition. In practice, the back-end computing platform 102 may generate the first partition and the second partition by defining bounding boxes for the partitions. As a result, the BIM data objects that were included in the retrieved partition may be included in either the first partition or the second partition, depending on where the BIM data objects are positioned.

In some implementations, a BIM data object may be wholly positioned in a given partition, and so the BIM data object may be included in that given partition. However, in other implementations, a BIM data object may be partially positioned in more than one partition, (e.g., in implementations where the BIM data object crosses the determined center of gravity of the retrieved partition). In implementations where the BIM data object is partially positioned in more than one partition, the back-end computing platform 102 may be configured to determine which partition a BIM data object is to be included in.

As one possibility, the back-end computing platform 102 may determine which partition a BIM data object is to be included in based on the center of gravity of the BIM data object, which, in line with the previous discussion, may be determined based on the geometry data of the BIM data object. For instance, if the BIM data object is partially positioned in a first partition and partially positioned in a second partition, and the center of gravity of the BIM data object is positioned in the first partition, then the back-end computing platform 102 may determine that the BIM data object is located in the first partition.

As another possibility, the back-end computing platform 102 may determine which partition a BIM data object is to be included in based on a geometric center of the BIM data object, which may be determined based on a bounding box of the BIM data object. For instance, if the BIM data object is partially positioned in a first partition and partially positioned in a second partition, and the geometric center of the BIM data object is positioned in the second partition, then the back-end computing platform 102 may determine that the BIM data object is located in the second partition.

At block 316, the back-end computing platform 102 may then add the first partition and the second partition to the set of partitions, which may each be retrieved by the back-end computing platform 102 in later iterations of block 308 for subsequent processing in line with the example operations shown in the flow diagram 300.

In implementations where the back-end computing platform 102 determines that the retrieved partition is not a large partition at block 310, the back-end computing platform 102 may proceed to block 318 instead of block 312.

At block 318, the back-end computing platform 102 may generate a partition file for the retrieved partition, which may include the geometry data for the BIM data objects included in the retrieved partition, as well as the object IDs for the BIM data objects included in the retrieved partition. The back-end computing platform 102 may store the generated partition file in storage of the back-end computing platform 102, among other possibilities.

After performing the operations of blocks 316 or 318 (e.g., depending on whether the retrieved partition is a large partition or not), the back-end computing platform 102 may return to block 308 to determine whether the set of partitions includes any other partitions. In line with the previous discussion, the back-end computing platform 102 may continue to iteratively perform operations of blocks 308-318 until the set of partitions is empty, which may indicate that the back-end computing platform 102 has (i) split the given BIM model into two or more partitions that each satisfies the partition size threshold and (ii) generated a respective partition file for each of the two or more partitions. In this way, each partition resulting from operations of the example flow diagram 300 satisfies the partition size threshold, and the back-end computing platform 102 has generated a partition file for each such partition.

In line with the previous discussion, some partitions may be generated in a manner different than that described with respect to blocks 312-314. For instance, a dedicated partition may be generated to include a large BIM data object (i.e., a BIM data object with enough geometry data to exceed the partition size threshold). Various other possibilities may also exist.

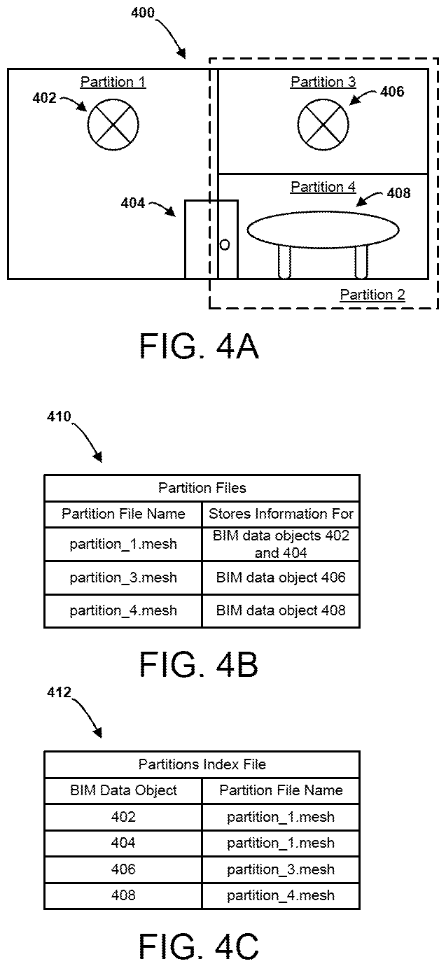

FIGS. 4A-4C provide an illustrative example showing how the back-end computing platform 102 may iteratively perform operations of FIG. 3 to split a given BIM model into one or more partitions that each satisfies a partition size threshold. For clarity and ease of illustration, FIG. 4A is depicted as a simplified two-dimensional drawing that includes relatively few BIM data objects. However, it will be appreciated from the discussion above that this example may be extended to three-dimensions and may be applied to BIM models including many more BIM data objects.

As shown, FIG. 4A depicts a BIM model 400 that includes BIM data objects 402-408 which represent a first window, a door, a second window, and a table, respectively.

In a first iteration of the example flow diagram 300, the back-end computing platform 102 may, after performing operations of blocks 302-306, retrieve a partition for the BIM model 400 from a set of partitions at block 308. In line with the previous discussion, the retrieved partition may define the entire space of the BIM model 400 (including the BIM data objects 402-408). At block 310, the back-end computing platform 102 may determine that the retrieved partition is a large partition, such as in the manner previously described. Then, at block 312, the back-end computing platform 102 may determine a center of gravity for the retrieved partition. In line with the previous discussion, the center of gravity may be perpendicular to the longest dimension of the given BIM model. Then, at block 314, the back-end computing platform 102 may split the retrieved partition into a first partition “Partition 1” including the BIM data objects 402 and 404 and a second partition “Partition 2” including the BIM data objects 406 and 408. As shown, the BIM data object 404 crosses the center of gravity between Partition 1 and Partition 2. In the example shown in FIG. 4A, the center of gravity of the BIM data object 404 may be positioned in Partition 1, and as a result, the BIM data object 404 may be included in Partition 1. Then, at block 316, the back-end computing platform 102 may add Partition 1 and Partition 2 to the set of partitions.

In a second iteration of the example flow diagram 300, the back-end computing platform 102 may: (i) at block 308, retrieve Partition 1, (ii) at block 310, determine that Partition 1 is not a large partition, and (iii) at block 318, generate a partition file for Partition 1.

In a third iteration of the example flow diagram 300, the back-end computing platform 102 may: (i) at block 308, retrieve Partition 2, (ii) at block 310, determine that Partition 2 is a large partition, (iii) at block 312, determine the center of gravity for Partition 2, (iv) at block 314, split Partition 2 into a first partition “Partition 3” including the BIM data object 406 and a second partition “Partition 4” including the BIM data object 408, and (v) at block 316, add Partition 3 and Partition 4 to the set of partitions.

In a fourth iteration of the example flow diagram 300, the back-end computing platform 102 may: (i) at block 308, retrieve Partition 3, (ii) at block 310, determine that Partition 3 is not a large partition, and (iii) at block 318, generate a partition file for Partition 3.

In a fifth iteration of the example flow diagram 300, the back-end computing platform 102 may: (i) at block 308, retrieve Partition 4, (ii) at block 310, determine that Partition 4 is not a large partition, and (iii) at block 318, generate a partition file for Partition 4.

As a result of performing these iterations of the example flow diagram 300, the back-end computing platform 102 may have generated a partition file for each of Partitions 1, 3, and 4. In line with the previous discussion, the back-end computing platform 102 may not have generated a partition file for the partition defining the entire space of the given BIM model 400 nor Partition 2, because neither satisfied the partition size threshold.

FIG. 4B illustrates a table 410 that shows the names for the partition files described with respect to FIG. 4A, as well as what information is contained in the partition files. As shown, the partition file for Partition 1 may be named “partition_1.mesh” and may contain information for the BIM data objects 402 and 404. In line with the previous discussion, this information may include, for each of the BIM data objects 402 and 404, (i) an object ID of the BIM data object and (ii) geometry data for the BIM data object.

As further shown, the partition file for Partition 3 may be named “partition_3.mesh” and may contain information for the BIM data object 406, which may include (i) an object ID of the BIM data object 406 and (ii) geometry data for the BIM data object 406.

As further shown, the partition file for Partition 4 may be named “partition_4.mesh” and may contain information for the BIM data object 408, which may include (i) an object ID of the BIM data object 408 and (ii) geometry data for the BIM data object 408.

Returning to FIG. 3, at block 320, the back-end computing platform 102 may generate a partitions index file to map each BIM data object of the given BIM model to the partition file in which the information for the BIM data object is stored. In practice, the partitions index file may take the form of a data structure that links object IDs to partition file names, for example via establishing key-value pairs between object IDs and partition file names.

One manner in which this may be done is shown in FIG. 4C. As shown, FIG. 4C includes a simplified representation of a partitions index file 412 that the back-end computing platform 102 may generate to map each of the BIM data objects 402-408 previously described to the respective partition file in which the information for the BIM data object is stored.

As shown, the partitions index file 412 maps: (i) the BIM data object 402 to the partition file named “partition_1.mesh,” using the object ID for the BIM data object 402, (ii) the BIM data object 404 to the partition file named “partition_1.mesh,” using the object ID for the BIM data object 404, (iii) the BIM data object 406 to the partition file named “partition_3.mesh,” using the object ID for the BIM data object 406, and (iv) the BIM data object 408 to the partition file named “partition_4.mesh,” using the object ID for the BIM data object 408. The partitions index file 412 may later be used by a client device during the rendering of the BIM model, as further discussed below.

FIGS. 4A-4C illustrate one example process by which the back-end computing platform 102 may perform the example functionality of the flow diagram 300 to (i) split the BIM model 400 into one or more partitions that each satisfies a partition size threshold (e.g., Partition 1, Partition 3, and Partition 4), (ii) generate a partition file for each of these partitions, and then (iii) generate a partitions index file to map each BIM data object of the BIM model 400 to the partition file in which the information for the BIM data object is stored. However, various other examples may also exist.

Further yet, although the example functionality of the flow diagram 300 has been described as being performed by the back-end computing platform 102, in at least some implementations, some or all of the example functionality of the flow diagram 300 may be performed by the client device 112 instead of, or possibly in combination with, the back-end computing platform 102. Similarly, operations of block 202 may also be performed by the client device 112 instead of, or possibly in combination with, the back-end computing platform 102.

Returning to FIG. 2, at block 204, a user of the client device 112 may input a request to view the given BIM model. In practice, the user may carry out this action by selecting the given BIM model (e.g., from a directory of available BIM models that can be accessed by the BIM viewing software application) and thereby requesting that the client device 112 present the given BIM model. However, the user's request to view the given BIM model may take other forms as well.

At block 206, the client device 112 may receive the user's request to view the given BIM model.

At block 208, the client device 112 may load information for generating a scene graph of the given BIM model (e.g., a simplified representation of a BIM model). In implementations where the information for generating the scene graph of the given BIM model is stored on the client device 112, the client device 112 may load the information by retrieving it from storage of the client device 112. Alternatively, in implementations where the information for generating the scene graph of the given BIM model is stored on the back-end computing platform 102 (or possibly on an external data store that is accessible to the back-end computing platform 102), the client device may load the information by first accessing the information from the back-end computing platform 102. For instance, as shown in FIG. 2, the client device 112 may transmit a request to the back-end computing platform 102 for the information for generating the scene graph of the given BIM model over the respective communication path 110 between the back-end computing platform 102 and the client device 112, and then at optional block 208′, the back-end computing platform 102 may (i) receive the request from the client device 112, (ii) retrieve the information for generating the scene graph of the given BIM model from the back-end computing platform's data storage (or from an external data store that is accessible to the back-end computing platform 102), and then (iii) transmit the information for generating the scene graph of the given BIM model back to the client device 112 over the respective communication path 110 between the back-end computing platform 102 and the client device 112. This may in turn result in the client device 112 receiving the information for generating the scene graph of the given BIM model from the back-end computing platform 102. In this way, the client device 112 may load the information for generating the scene graph of the given BIM model by virtue of requesting and receiving the information from the back-end computing platform 102.

The client device 112 may access the information for generating the scene graph of the given BIM model for loading in various other ways as well.

Further, the information for generating the scene graph of the given BIM model may take various forms. As one possibility, the information for generating the scene graph of the given BIM model may include a file or the like that maps each BIM data object of the given BIM model with the object ID of the BIM data object. As another possibility, the information for generating the scene graph of the given BIM model may include the partitions index file generated by the back-end computing platform 102 at block 320 of FIG. 3. Various other possibilities may also exist.

At block 210, the client device 112 may generate a scene graph for the given BIM model. As referenced herein, a “scene graph” may refer to a simplified representation of a BIM model and may include features such as (i) bounding boxes for BIM data objects of the given BIM model, and possibly (ii) object IDs corresponding to the bounding boxes for the BIM data objects in the scene graph. In practice, the scene graph for the given BIM model may include more or fewer features than those described, and the features described are intended to be illustrative only.

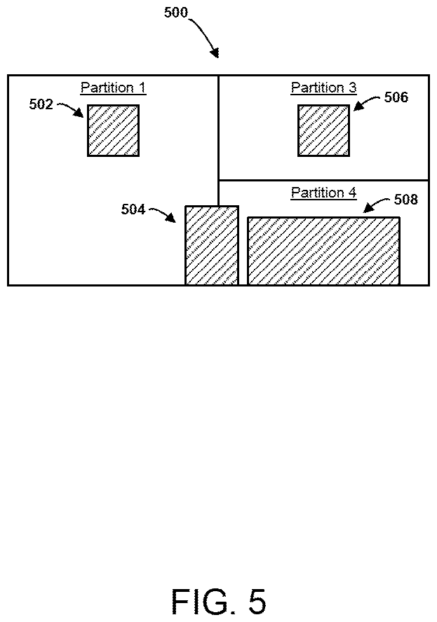

FIG. 5 shows simplified illustration of a scene graph 500 that may be generated by the client device at block 210 of FIG. 2. As shown, the scene graph 500 is similar to the example BIM model 400 of FIG. 4A, except that instead of including fully rendered BIM data objects 402-408, the scene graph 500 includes (i) a bounding box 502 for the BIM data object 402, (ii) a bounding box 504 for the BIM data object 404, (iii) a bounding box 506 for the BIM data object 406, and (iv) a bounding box 508 for the BIM data object 408. Further, in line with the previous discussion, the scene graph 500 may also include the object IDs for the BIM data objects 402-408, each of which may be mapped to the corresponding bounding box.

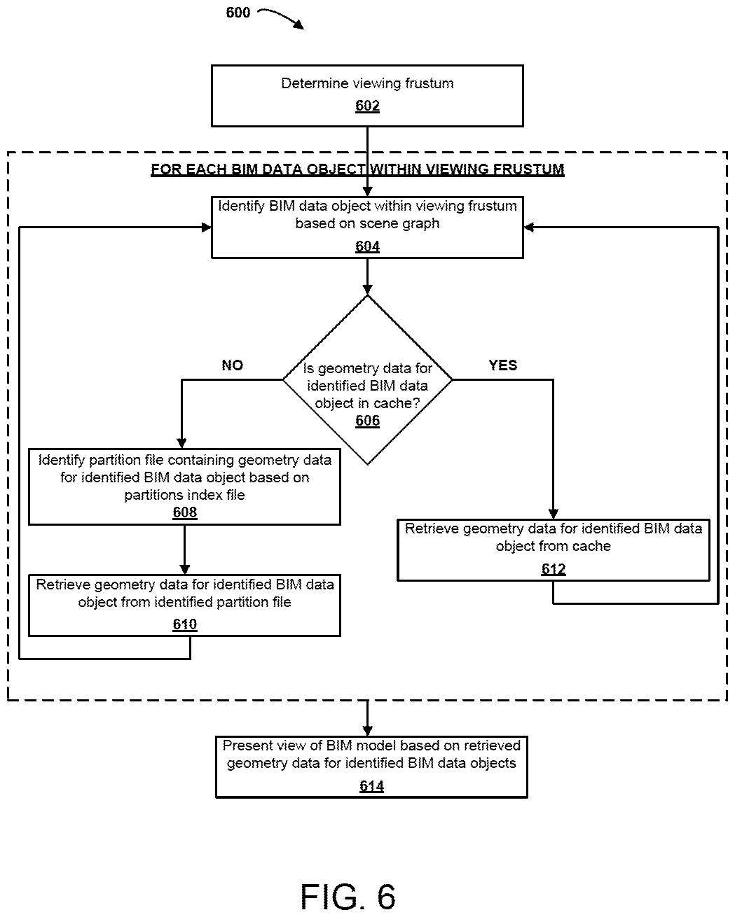

Returning to FIG. 2, at block 212, the client device 112 may present an initial view of the given BIM model based on the generated scene graph. In practice, this may involve accessing geometry data for one or more BIM data objects that are to be included in the initial view of the given BIM model, and then rendering the one or more BIM data objects based on the geometry data. As described in greater detail below with respect to FIG. 6, this may involve accessing geometry data from local storage of the client device 112, and may also involve accessing geometry data from the back-end computing platform 102. For instance, as shown in FIG. 2, the client device 112 may transmit a request to the back-end computing platform 102 for the geometry data for one or more BIM data objects. At optional block 212′, the back-end computing platform 102 may (i) receive the request from the client device 112 to access the geometry data for one or more BIM data objects, (ii) retrieve the geometry data for one or more BIM data objects from the back-end computing platform's data storage (or from an external data store that is accessible to the back-end computing platform 102), and then (iii) transmit the geometry data for one or more BIM data objects back to the client device 112. This may in turn result in the client device 112 receiving the geometry data for one or more BIM data objects from the back-end computing platform 102. In this way, the client device 112 may access the geometry data for one or more BIM data objects by virtue of requesting and receiving the geometry data for one or more BIM data objects from the back-end computing platform 102.

FIG. 6 includes a flow diagram 600 showing example functionality that may be performed by the client device 112 to present a given view (e.g., an initial view, an updated view, etc.) of the given BIM model based on the generated scene graph.

Starting at block 602, the client device 112 may determine a viewing frustum for the given view of the given BIM model. As used herein, a “viewing frustum” may refer to the portion of the given view of the BIM model that is visible based on a viewing position and angle within the BIM model, sometimes referred to as a “camera position and angle.” The portion of the BIM model that is presented via the client device 112 running the BIM viewing software application is then based on the viewing frustum.

After determining the viewing frustum for the given view of the given BIM model, the client device 112 may iteratively perform operations of blocks 604-614 to present the BIM data objects that are within the viewing frustum.

At block 604, the client device 112 may identify a BIM data object that is within the viewing frustum. To identify a BIM data object, the client device 112 may compare the determined viewing frustum with the generated scene graph to determine whether a BIM data object bounding box intersects the viewing frustum. If a BIM data object bounding box intersects the viewing frustum, then the client device 112 may identify the BIM data object based on the object ID that is associated with the BIM data object bounding box that intersects the viewing frustum. For instance, the client device 112 may parse the file mapping each BIM data object of the given BIM model with the object ID of the BIM data object to identify the BIM data object matching the object ID associated with the BIM data object bounding box.

At block 606, the client device 112 may determine whether geometry data for the identified BIM data object is stored in a cache of the client device 112. The cache of the client device 112 may function to temporarily store a limited amount of geometry data that was previously accessed by the client device 112. For instance, after accessing geometry data for a given BIM data object, as described in greater detail below, the client device 112 may store the geometry data for the given BIM data object in the local cache and generate a handle that may be used by the client device 112 to access the geometry data from the local cache at a later time. This handle may take the form of a pointer or other reference to a location in the local cache where the geometry data for the given BIM data object is stored.

In some implementations, the cache of the client device 112 may be integrated with other components of the client device 112. Additionally or alternatively, in some implementations, the cache of the client device 112 may be a dedicated cache, which may be an internal component of the client device 112 or which may possibly be external to the client device 112. Further, the cache of the client device may take any of various forms, one example being a graphical processing unit (GPU) of the client device 112. Various other possibilities may also exist.

As the cache of the client device 112 may have limited storage capacity, the cache may be configured to refresh according to a cache eviction policy, which may determine how data stored in the cache is to be evicted (e.g., to make space for incoming data to be stored in the cache). One possible cache eviction policy may be least-recently-used (LRU) cache eviction policy, in which geometry data for a given BIM data object stored in the cache is labeled with an indicator of when the geometry data was last accessed (e.g., read) by the client device 112. When the cache has reached its storage capacity, the cache may evict geometry data for one or more BIM data objects stored in the cache that was least recently used. In practice, the cache may accomplish this by (i) receiving a request to store new geometry data for a BIM data object data in the cache, (ii) determining the amount of storage that will be required to store the new geometry data in the cache, (iii) determining an amount of geometry data for one or more BIM data objects currently stored in the cache that (a) was least recently used and that (b) takes up the determined amount of storage that will be required to store the new geometry data in the cache, and then (iv) evicting the amount of geometry data for one or more BIM data objects currently stored in the cache.

Another cache eviction policy may include a FIFO cache eviction policy, in which the geometry data for BIM data objects that have been stored in the cache for the longest period of time (i.e., that were first stored in the cache) are evicted when the cache fills up.

Yet another cache eviction policy may include a time-based cache eviction policy, in which geometry data for BIM data objects stored in the cache are evicted after a given period of time. In practice, this time-based cache eviction policy may be enacted as the cache fills, and once the cache has filled up, other cache eviction policies may also be utilized, such as the LRU cache policy or FIFO cache policy described. In practice, various other cache eviction policies may also exist, which may be enacted at various times to manage the storage of the cache of the client device 112.

In addition to storing geometry data for BIM data objects, the cache of the client device 112 may also store the object IDs for the BIM data objects, and the client device 112 may determine whether geometry data for the identified BIM data object is stored in the cache of the client device 112 based on the object IDs stored in the cache. To accomplish this, the client device 112 may compare the object ID associated with the identified BIM data object with the object IDs stored in the cache of the client device 112. If the object ID associated with the identified BIM data object is not in the cache of the client device 112, then the client device 112 may proceed to block 608. Alternatively, if the object ID associated with the identified BIM data object is in the cache of the client device 112, then the client device 112 may proceed to block 612 instead, as described in greater detail below.

At block 608, after determining that the geometry data for the identified BIM data object is not stored in the cache of the client device 112, the client device 112 may identify the partition file that contains the geometry data for the identified BIM data object. In practice, the client device 112 may accomplish this by utilizing the partitions index file, which, as previously described, may be included in the information loaded by the client device 112 at block 208. Specifically, the client device 112 may locate the object ID of the identified BIM data object within the partitions index file and then identify the partition file that includes the geometry data for the identified BIM data object, e.g., by identifying the partition file to which the object ID of the identified BIM data object is mapped.

At block 610, the client device 112 may retrieve the geometry data for the identified BIM data object from the partition file identified at block 608. The manner by which the client device 112 may accomplish this may take various forms.

As one possibility, the client device 112 may retrieve the geometry data for the identified BIM data object from the identified partition file along with geometry data for each other BIM data objects that are also stored in the identified partition file. In practice, the client device 112 may retrieve the geometry data stored in the identified partition file either (i) from the back-end computing platform 102 or possibly (ii) from local storage of the client device 112 (e.g., permanent storage, as opposed to the cache of the client device 112).

In implementations where the identified partition file is stored by the back-end computing platform 102 (or possibly in external storage that is accessible to the back-end computing platform 102), then the client device 112 may retrieve the geometry stored in the identified partition from the back-end computing platform 102. For instance, the client device 112 may transmit a request to the back-end computing platform 102 for the geometry data stored in the identified partition file over the respective communication path 110 between the back-end computing platform 102 and the client device 112. The request may include the partition file name of the identified partition file, or some other identifier (e.g., a uniform resource location, or URL) of the identified partition file. Then, in line with the previous discussion of optional block 212′ of FIG. 2, the back-end computing platform 102 may (i) receive the request from the client device 112 to access the geometry data stored in the identified partition file, (ii) retrieve the geometry data stored in the identified partition file from the back-end computing platform's data storage (or from an external data store that is accessible to the back-end computing platform 102), and then (iii) transmit the geometry data stored in the identified partition file back to the client device 112. This may in turn result in the client device 112 receiving the geometry data stored in the identified partition file from the back-end computing platform 102. In this way, the client device 112 may access the geometry data stored in the identified partition file by virtue of requesting and receiving the geometry from the back-end computing platform 102.

Alternatively, in implementations where the identified partition file is stored in local storage of the client device 112, the client device 112 may retrieve the geometry data stored in the identified partition by accessing the geometry data from the identified partition file stored in the local storage of the client device 112.

Once the client device 112 has retrieved the geometry data stored in the identified partition, whether from the back-end computing platform 102 or from local storage of the client device 112, the client device 112 may then identify the geometry data for the identified BIM data object from the retrieved geometry data, for instance, using the object ID of the identified BIM data object.

As another possibility, the client device 112 may retrieve the geometry data for the identified BIM data object from the identified partition file in isolation, without retrieving the geometry data for other BIM data objects stored in the identified partition file. In practice, this may be similar to the manner by which the client device 112 retrieves the geometry data stored in the identified partition file, with the possible exception that the request transmitted by the client device 112 to the back-end computing platform 102 for the geometry data of the identified BIM data object may differ from the request for the geometry data stored in the identified partition file. As previously mentioned, the request for the geometry data stored in the identified partition file that is sent by the client device 112 to the back-end computing platform 102 may include an identifier of the identified partition file (e.g., the name of the identified partition file). The request for the geometry data for the identified BIM data object, on the other hand, may include the object ID of the identified BIM data object, in addition to or possibly instead of the identifier of the identified partition file. In implementations where the request includes the object ID of the identified BIM data object in addition to the identifier of the identified partition file, the back-end computing platform 102 may utilize the object ID to locate the geometry data of the identified BIM data object from the identified partition file. Alternatively, in implementations where the requests includes the object ID of the identified BIM data object instead of the identifier of the identified partition file, the back-end computing platform 102 may be configured to perform operations of block 608 to identify the partition file based on the received object ID of the identified BIM data object and thereafter locate the geometry data of the identified BIM data object from the identified partition file. Various other possibilities may also exist.

In line with the previous discussion, in some implementations, the client device 112 may determine at block 606 that the geometry data for the identified BIM data object is included in the cache of the client device 112. After such a determination, the client device may proceed from block 606 to block 612 instead of block 608.

At block 612, the client device 112 may retrieve the geometry data for the identified BIM data object from the cache of the client device 112. This operation may take various forms. As one possibility, the client device 112 may retrieve the geometry data using the handle that was generated when the geometry data for the identified BIM data object was initially stored in the cache.

As another possibility, the client device 112 may retrieve the geometry data using the object ID of the identified BIM data object. For instance, the client device 112 may (i) parse through the object IDs stored in the cache to identify the object ID that matches the object ID included in the query, (ii) based on identifying the matching object ID, identify the geometry data stored in the cache that is associated with the matching object ID, and then (iii) retrieve the identified geometry data from the cache.

After retrieving the geometry data for the identified BIM data object, either at block 612 or at block 610, the client device 112 may then iteratively repeat operations of blocks 604-612 until the geometry data for each BIM data object within the viewing frustum has been retrieved.

Due to the iterative nature of the example functionality shown in the flow diagram 600, over the course of presenting one or more views of the given BIM data object during a runtime session of the BIM viewing software application, the client device 112 may communicate with the back-end computing platform 102 various times, e.g., to retrieve geometry data for one or more BIM data objects that are to be included in views of the given BIM model. In some implementations, to reduce computing resource costs, the client device 112 may be configured to establish a web socket connection with the back-end computing platform 102, so that communications between the client device 112 and the back-end computing platform 102 during the runtime session of the BIM viewing software application may not need to be reinitiated with every communication.

After retrieving the geometry data for each BIM data object within the viewing frustrum, at block 614 the client device 112 may, while running a BIM viewing software application that incorporates the disclosed BIM model rendering tool, present a view of the given BIM model based on the retrieved geometry data for the identified BIM data objects. In line with the previous discussion, the presented view may correspond to the determined viewing frustum, and may include visualizations of one or more of the BIM data objects identified via the block 604.

Further, in some implementations, the client device 112 may be configured to store the geometry data retrieved via the example operations shown in the flow diagram 600 in the cache of the client device 112 for future use. For instance, the client device 112 may store geometry data in the cache that the client device 112 retrieved from one or more partition files, as described with respect to block 610. In line with the previous discussion, this may include storing the geometry data for identified BIM data objects and may further include storing the geometry data for other BIM data objects that are included in the partition file(s) from which the geometry data for the identified BIM data objects were retrieved. As described in greater detail below, this may be of particular benefit for future iterations of the example operations in the flow diagram 600, so that the client device 112 may be able to retrieve geometry data of the given BIM model from the cache of the client device 112, rather than from a partition file.

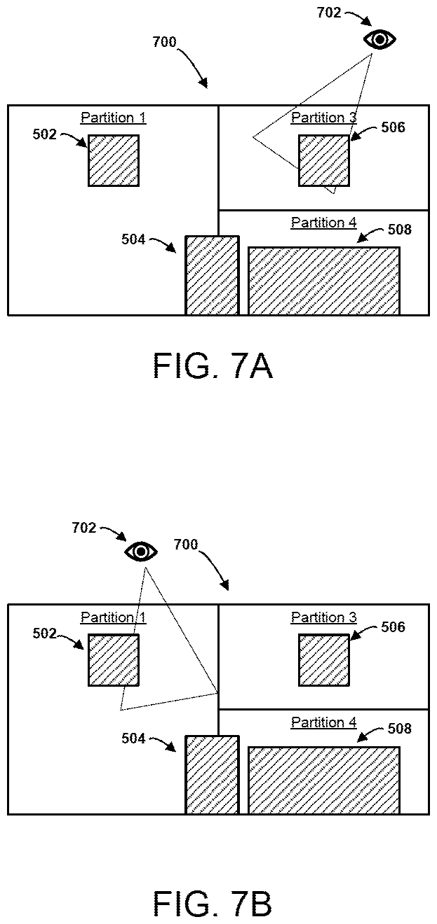

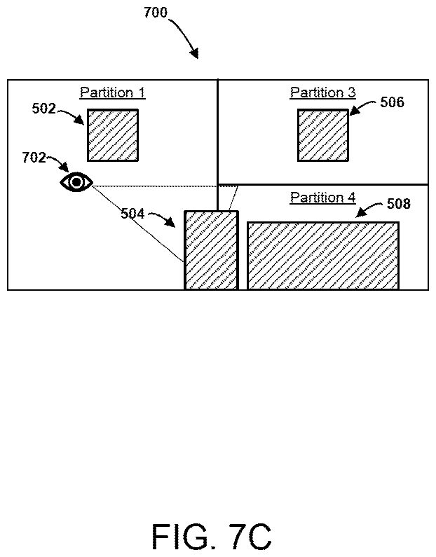

FIG. 7A shows an example visualization 700 that illustrates some of the example operations that the client device 112 may perform to present an initial view of the given BIM model. As shown, the example visualization 700 includes a viewing frustum 702 located at an initial position within the scene graph 500. In the example visualization 700, the viewing frustum 702 includes a portion of the bounding box 506, located in Partition 3. In accordance with the description above, the client device 112 may, at block 604, identify the BIM data object 406 as being within the viewing frustum 702 based on the bounding box 506 intersecting the viewing frustum 702. Then, at block 606, the client device 112 may determine that the geometry data for the BIM data object 406 is not stored in the cache of the client device 112. In practice, this may be because the example visualization 700 shows how the client device 112 may perform the example operations to present an initial view of the given BIM model, and the cache of the client device 112 may be empty. Based on determining that the geometry data for the BIM data object 406 is not stored in the cache of the client device 112, the client device 112 may then, at block 608, identify the partition file for Partition 3 based on the partitions index file, as previously described. At block 610, the client device 112 may retrieve the geometry data for the BIM data object 406 from the identified partition file, as previously described. After retrieving the geometry data for the BIM data object 406, the client device may, at block 614, present an initial view of the given BIM model including a visualization of the BIM data object 406, as previously described. Further, and in line with the previous discussion, the geometry data for the BIM data object 406 may be stored in the cache of the client device 112 for future use.

Returning to FIG. 2, at block 214, the user of the client device 112 may input a request to navigate the view of the given BIM model. In practice, the user may carry out this action by interacting with one or more selectable icons presented by the client device 112 that enable the user to navigate the view of the given BIM model (e.g., controls for moving a virtual camera throughout the given BIM model). However, the user's request to navigate the view of the given BIM model may take other forms as well.

At block 216, the client device 112 may receive the user's request to navigate the view of the given BIM model.

At block 218, the client device 112 may present an updated view of the given BIM model based on the generated scene graph. In practice, the operations of block 218 may be similar to the operations of block 212, and the example functionality shown in the flow diagram 600 of FIG. 6 may apply to the updated view of the given BIM model as well as the initial view of the given BIM model. Further, in practice, presenting an updated view of the given BIM model may also include removing BIM data objects that are no longer in the viewing frustum.

FIGS. 7B and 7C illustrate certain features described with respect to the example operations shown in the flow diagram 600 that are involved in presenting updated views of the given BIM model.

Starting with FIG. 7B, the viewing frustum 702 has moved from the initial position shown in FIG. 7A to a new location. As shown in FIG. 7B, the viewing frustum 702 now includes a portion of the bounding box 502, which is included in Partition 1. In accordance with the description above, the client device 112 may, at block 604, identify the BIM data object 402 as being within the viewing frustum 702 based on the bounding box 502 intersecting the viewing frustum 702. Then, at block 606, the client device 112 may determine that the geometry data for the BIM data object 402 is not stored in the cache of the client device 112, which at this time may only include the geometry data for the BIM data object 406, as described with respect to FIG. 7A. Based on determining that the geometry data for the BIM data object 402 is not stored in the cache of the client device 112, the client device 112 may then, at block 608, identify the partition file for Partition 1 based on the partitions index file, as previously described. At block 610, the client device 112 may retrieve the geometry data for the BIM data object 402 from the identified partition file, as previously described. Further, the client device 112 may also retrieve any other geometry data stored in the identified partition file, which in this example may include the geometry data for the BIM data object 404, as previously described. After retrieving the geometry data for the BIM data object 402, the client device may, at block 614, present an updated view of the given BIM model including a visualization of the BIM data object 402, as previously described. Further, and in line with the previous discussion, the geometry data for the BIM data objects 402 and 404 may be stored in the cache of the client device 112 for future use.

Turning to FIG. 7C, the viewing frustum 702 has moved again (e.g., based on a user navigation request) from the position shown in FIG. 7B to a new location. As shown in FIG. 7C, the viewing frustum 702 now includes a portion of the bounding box 504. In accordance with the description above, the client device 112 may, at block 604, identify the BIM data object 404 as being within the viewing frustum 702 based on the bounding box 504 intersecting the viewing frustum 702. Then, at block 606, the client device 112 may determine that the geometry data for the BIM data object 404 is stored in the cache of the client device 112, which as previously described may have been occurred when the geometry data for the BIM data object was retrieved from the partition file for the Partition 1. Based on determining that the geometry data for the BIM data object 402 is stored in the cache of the client device 112, the client device 112 may then, at block 612, retrieve the geometry data for the BIM data object 404 from the cache of the client device 112, as previously described. After retrieving the geometry data for the BIM data object 404, the client device may, at block 614, present an updated view of the given BIM model including a visualization of the BIM data object 404, as previously described. It should be noted that although a portion of Partition 4 is included in the viewing frustum 702, as shown in FIG. 7C, no BIM data object bounding box for a BIM data object that is included in the Partition 4 is included in the viewing frustum 702. As a result, the partition file for the Partition 4 may not be accessed by the client device 112.

FIGS. 7A-7C show only some of the possible ways in which the client device 112 may perform the example operations shown in the flow diagram 600. In practice, the client device 112 may perform the operations in various other ways to present a view (e.g., an initial or updated view) of the given BIM data object. Further, in practice, the operations of blocks 214-218 (including optional block 218′) may be performed any number of times during a given runtime session of the BIM viewing software application, as the user of the client device 112 may wish to perform various navigations within the given BIM model.

Further, in practice, the client device 112 running a BIM viewing software application that utilizes the disclosed BIM model rendering tool may be configured to determine whether or not a BIM model that is to be presented has been partitioned by the BIM model partitioning tool. In implementations where the client device 112 determines that the BIM model has been partitioned, then the client device 112 may be configured to perform the example operations shown in the flow diagram 200 and the example operations shown in the flow diagram 600 to render the BIM model on an as-needed basis based on the partitions generated by the back-end computing platform 102 via the BIM model partitioning tool. Further, in implementations where the client device 112 determines that the BIM model has not been partitioned, as well as possibly that the BIM model is not a large BIM model, then the client device 112 may be configured to render the BIM model without utilizing the various functionality described herein regarding utilizing the generated partition files for partitions of the BIM model. Rather, the client device 112 may instead render the BIM model in a default manner, e.g., by loading all of the geometry data for the BIM data objects of the BIM model directly from the one or more BIM files that store the geometry data for the BIM data objects. Various other possibilities may also exist.

Further yet, the client device 112 and/or the back-end computing platform 102 may implement additional strategies to reduce the size of information that is accessed by the client device 112 for the given BIM model. One such strategy may include adjusting the amount of geometry data that is used to render a given BIM data object, which may be referred to as a “Level of Detail” approach. For example, the client device 112 and/or the back-end computing platform 102 may determine that a given BIM data object only needs to include a percentage of the resolution that the geometry data of the given BIM data object may support. In such examples, the client device 112 and/or the back-end computing platform 102 may reduce the amount of geometry data that is used to render the given BIM data object, e.g., by removing or otherwise not utilizing some of the geometry data when rendering the BIM data object. To accomplish this, the client device 112 and/or the back-end computing platform 102 may replace geometry data for high-resolution areas of the given BIM data object with geometry data that defines a lower-resolution version of the areas of the given BIM data object. Various other examples may also exist. In practice, this strategy may be particularly useful for BIM data objects that are positioned far away within the viewing frustum, as such BIM data objects may not ordinarily need to be presented with a high level of resolution. Various other strategies may also be utilized.

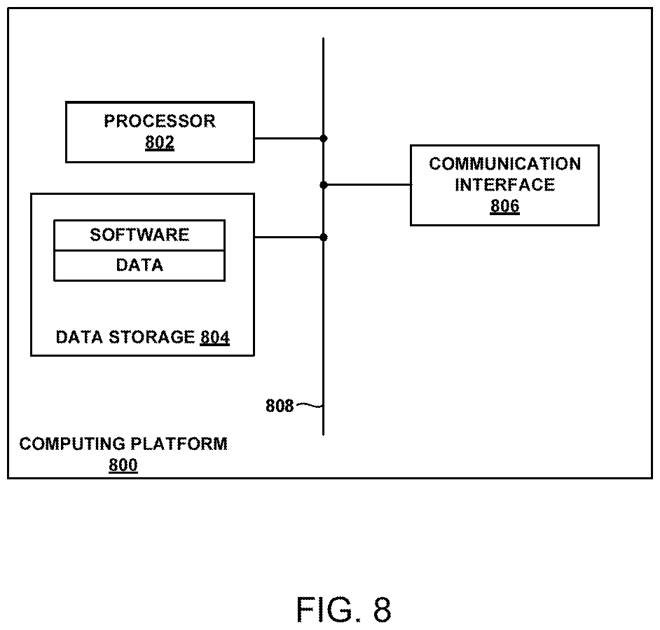

Turning now to FIG. 8, a simplified block diagram is provided to illustrate some structural components that may be included in an example computing platform 800 that may be configured to perform some or all of the server-side functions disclosed herein. At a high level, the example computing platform 800 may generally comprise any one or more computer systems (e.g., one or more servers) that collectively include one or more processors 802, data storage 804, and one or more communication interfaces 806, all of which may be communicatively linked by a communication link 808 that may take the form of a system bus, a communication network such as a public, private, or hybrid cloud, or some other connection mechanism. Each of these components may take various forms.

For instance, the one or more processors 802 may comprise one or more processor components, such as one or more central processing units (CPUs), graphics processing unit (GPUs), application-specific integrated circuits (ASICs), digital signal processor (DSPs), and/or programmable logic devices such as field programmable gate arrays (FPGAs), among other possible types of processing components. In line with the discussion above, it should also be understood that the one or more processors 802 could comprise processing components that are distributed across a plurality of physical computing devices connected via a network, such as a computing cluster of a public, private, or hybrid cloud.

In turn, the data storage 804 may comprise one or more non-transitory computer-readable storage mediums, examples of which may include volatile storage mediums such as random-access memory, registers, cache, etc. and non-volatile storage mediums such as read-only memory, a hard-disk drive, a solid-state drive, flash memory, an optical-storage device, etc. In line with the discussion above, it should also be understood that the data storage 804 may comprise computer-readable storage mediums that are distributed across a plurality of physical computing devices connected via a network, such as a storage cluster of a public, private, or hybrid cloud that operates according to technologies such as AWS for Elastic Compute Cloud, Simple Storage Service, etc.

As shown in FIG. 8, the data storage 804 may be capable of storing both (i) program instructions that are executable by the one or more processors 802 such that the example computing platform 800 is configured to perform any of the various functions disclosed herein (including but not limited to any of the server-side functions discussed above), and (ii) data that may be received, derived, or otherwise stored by the example computing platform 800.

The one or more communication interfaces 806 may comprise one or more interfaces that facilitate communication between the example computing platform 800 and other systems or devices, where each such interface may be wired and/or wireless and may communicate according to any of various communication protocols. As examples, the one or more communication interfaces 806 may take include an Ethernet interface, a serial bus interface (e.g., Firewire, USB 3.0, etc.), a chipset and antenna adapted to facilitate any of various types of wireless communication (e.g., Wi-Fi communication, cellular communication, Bluetooth® communication, etc.), and/or any other interface that provides for wireless or wired communication. Other configurations are possible as well.

Although not shown, the example computing platform 800 may additionally have an I/O interface that includes or provides connectivity to I/O components that facilitate user interaction with the example computing platform 800, such as a keyboard, a mouse, a trackpad, a display screen, a touch-sensitive interface, a stylus, a virtual-reality headset, and/or one or more speaker components, among other possibilities.

It should be understood that the example computing platform 800 is one example of a computing platform that may be used with the embodiments described herein. Numerous other arrangements are possible and contemplated herein. For instance, in other embodiments, the example computing platform 800 may include additional components not pictured and/or more or less of the pictured components.

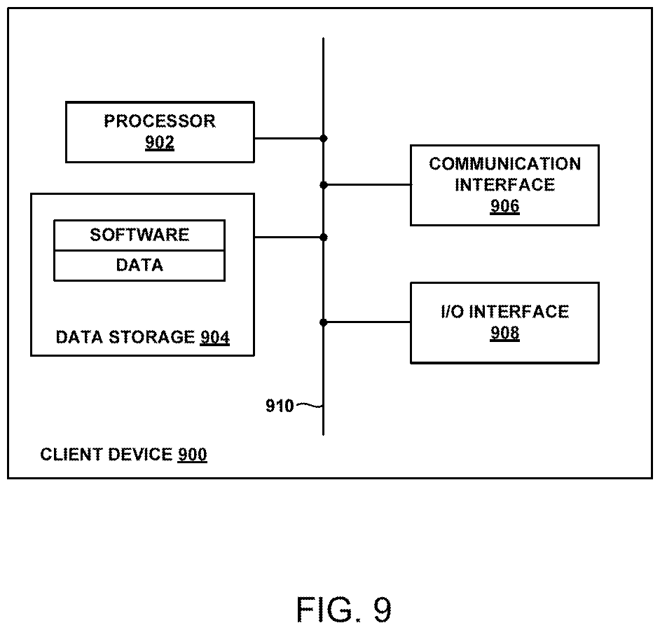

Turning next to FIG. 9, a simplified block diagram is provided to illustrate some structural components that may be included in an example client device 900 that may be configured to perform some or all of the client-side functions disclosed herein. At a high level, the example client device 900 may include one or more processors 902, data storage 904, one or more communication interfaces 906, and an I/O interface 908, all of which may be communicatively linked by a communication link 910 that may take the form a system bus and/or some other connection mechanism. Each of these components may take various forms.

For instance, the one or more processors 902 of the example client device 900 may comprise one or more processor components, such as one or more CPUs, GPUs, ASICs, DSPs, and/or programmable logic devices such as FPGAs, among other possible types of processing components.

In turn, the data storage 904 of the example client device 900 may comprise one or more non-transitory computer-readable mediums, examples of which may include volatile storage mediums such as random-access memory, registers, cache, etc. and non-volatile storage mediums such as read-only memory, a hard-disk drive, a solid-state drive, flash memory, an optical-storage device, etc. As shown in FIG. 9, the data storage 904 may be capable of storing both (i) program instructions that are executable by the one or more processors 902 of the example client device 900 such that the example client device 900 is configured to perform any of the various functions disclosed herein (including but not limited to any of the client-side functions discussed above), and (ii) data that may be received, derived, or otherwise stored by the example client device 900.

The one or more communication interfaces 906 may comprise one or more interfaces that facilitate communication between the example client device 900 and other systems or devices, where each such interface may be wired and/or wireless and may communicate according to any of various communication protocols. As examples, the one or more communication interfaces 906 may take include an Ethernet interface, a serial bus interface (e.g., Firewire, USB 3.0, etc.), a chipset and antenna adapted to facilitate any of various types of wireless communication (e.g., Wi-Fi communication, cellular communication, Bluetooth® communication, etc.), and/or any other interface that provides for wireless or wired communication. Other configurations are possible as well.

The I/O interface 908 may generally take the form of (i) one or more input interfaces that are configured to receive and/or capture information at the example client device 900 and (ii) one or more output interfaces that are configured to output information from the example client device 900 (e.g., for presentation to a user). In this respect, the one or more input interfaces of I/O interface may include or provide connectivity to input components such as a microphone, a camera, a keyboard, a mouse, a trackpad, a touchscreen, and/or a stylus, among other possibilities, and the one or more output interfaces of the I/O interface 908 may include or provide connectivity to output components such as a display screen and/or an audio speaker, among other possibilities.

It should be understood that the example client device 900 is one example of a client device that may be used with the example embodiments described herein. Numerous other arrangements are possible and contemplated herein. For instance, in other embodiments, the example client device 900 may include additional components not pictured and/or more or fewer of the pictured components.

### CONCLUSION

Example embodiments of the disclosed innovations have been described above. Those skilled in the art will understand, however, that changes and modifications may be made to the embodiments described without departing from the true scope and spirit of the present invention, which will be defined by the claims.

For instance, those in the art will understand that the disclosed software technology may be implemented in areas other than construction and construction-related projects and may be used in other ways as well.

Further, to the extent that examples described herein involve operations performed or initiated by actors, such as “humans,” “operators,” “users,” or other entities, this is for purposes of example and explanation only. The claims should not be construed as requiring action by such actors unless explicitly recited in the claim language.

1. A computing platform comprising:
at least one processor;
at least one computer-readable medium; and
program instructions stored on the at least one computer-readable medium that are executable by the at least one processor such that the computing platform is configured to:
access a set of information encoding geometry data for a plurality of building information model (BIM) data objects for a given BIM model;
add a partition for the given BIM model to a set of partitions, wherein the partition for the given BIM model comprises the plurality of BIM data objects;
for each partition of one or more partitions that each satisfies a partition size threshold, generate a respective partition file by, while the set of partitions includes a partition that does not satisfy the partition size threshold:
retrieving a partition from the set of partitions;
determining whether the retrieved partition satisfies the partition size threshold;
based on determining that the retrieved partition does not satisfy the partition size threshold, (i) determining a center of gravity for the retrieved partition, (ii) splitting the retrieved partition into (a) a first partition that falls to a first side of the determined center of gravity for the retrieved partition and (b) a second partition that falls to a second side of the determined center of gravity for the retrieved partition, and (iii) adding the first partition and the second partition to the set of partitions; and
based on determining that the retrieved partition satisfies the partition size threshold, generating a partition file for the retrieved partition; and
generate a partitions index file mapping each BIM data object of the plurality of BIM data objects to a corresponding generated partition file.

2. The computing platform of claim 1, wherein the program instructions that are executable by the at least one processor such that the computing platform is configured to determine the center of gravity comprise program instructions that are executable by the at least one processor such that the computing platform is configured to determine the center of gravity for the retrieved partition along a longest dimension of the retrieved partition.

3. The computing platform of claim 1, wherein the program instructions that are executable by the at least one processor such that the computing platform is configured to determine the center of gravity comprise program instructions that are executable by the at least one processor such that the computing platform is configured to determine the center of gravity for the retrieved partition based on the geometry data of BIM data objects of the retrieved partition.

4. The computing platform of claim 1, wherein the geometry data for a given BIM data object of the plurality of BIM data objects comprises: (i) a number of vertices of the given BIM data object and (ii) a number of triangular faces of the given BIM data object.

5. The computing platform of claim 1:
wherein the program instructions that are executable by the at least one processor such that the computing platform is configured to access the set of information comprise program instructions that are executable by the at least one processor such that the computing platform is configured to access the set of information from a given BIM file; and
further comprising program instructions stored on the at least one non-transitory computer-readable medium that are executable by the at least one processor such that the computing platform is configured to determine that the set of information accessed from the given BIM file exceeds a threshold size.

6. The computing platform of claim 5, wherein the program instructions that are executable by the at least one processor such that the computing platform is configured to add the partition for the given BIM model to the set of partitions comprise program instructions that are executable by the at least one processor such that the computing platform is configured to add the partition for the given BIM model to the set of partitions based on determining that the set of information accessed from the given BIM file exceeds the threshold size.

7. The computing platform of claim 1, further comprising program instructions stored on the at least one non-transitory computer-readable medium that are executable by the at least one processor such that the computing platform is configured to:
transmit the generated partitions index file to a client device for use in rendering the given BIM model.

8. The computing platform of claim 1, wherein the generated partition file for the retrieved partition includes geometry data for one or more BIM data objects included in the retrieved partition.

9. The computing platform of claim 8, further comprising program instructions stored on the at least one non-transitory computer-readable medium that are executable by the at least one processor such that the computing platform is configured to:
transmit the geometry data for the one or more BIM data objects included in the retrieved partition to a client device for use in rendering the given BIM model.

10. The computing platform of claim 1, wherein the first partition includes BIM data objects that fall to the first side of the determined center of gravity for the retrieved partition, and wherein the second partition includes BIM data objects that fall to the second side of the determined center of gravity for the retrieved partition.

11. The computing platform of claim 10, wherein a given BIM data object falls to either the first side of the determined center of gravity for the retrieved partition or the second side of the determined center of gravity for the retrieved partition based on a given center of gravity of the given BIM data object, wherein the given center of gravity of the given BIM data object is based on the geometry data of the given BIM data object.

12. The computing platform of claim 11, wherein a given BIM data object falls to either the first side of the determined center of gravity for the retrieved partition or the second side of the determined center of gravity for the retrieved partition based on a given geometric center of the given BIM data object.

13. A non-transitory computer-readable medium, wherein the non-transitory computer-readable medium is provisioned with program instructions that, when executed by at least one processor, cause a computing platform to:
access a set of information encoding geometry data for a plurality of building information model (BIM) data objects for a given BIM model;
add a partition for the given BIM model to a set of partitions, wherein the partition for the given BIM model comprises the plurality of BIM data objects;
for each partition of one or more partitions that each satisfies a partition size threshold, generate a respective partition file by, while the set of partitions includes a partition that does not satisfy the partition size threshold:
retrieving a partition from the set of partitions;
determining whether the retrieved partition satisfies the partition size threshold;
based on determining that the retrieved partition does not satisfy the partition size threshold, (i) determining a center of gravity for the retrieved partition, (ii) splitting the retrieved partition into (a) a first partition that falls to a first side of the determined center of gravity for the retrieved partition and (b) a second partition that falls to a second side of the determined center of gravity for the retrieved partition, and (iii) adding the first partition and the second partition to the set of partitions; and
based on determining that the retrieved partition satisfies the partition size threshold, generating a partition file for the retrieved partition; and
generate a partitions index file mapping each BIM data object of the plurality of BIM data objects to a corresponding generated partition file.

14. The non-transitory computer-readable medium of claim 13, wherein the program instructions that, when executed by at least one processor, cause the computing platform to determine the center of gravity comprise program instructions that, when executed by at least one processor, cause the computing platform to determine the center of gravity for the retrieved partition along a longest dimension of the retrieved partition.

15. The non-transitory computer-readable medium of claim 13, wherein the program instructions that, when executed by at least one processor, cause the computing platform to determine the center of gravity comprise program instructions that, when executed by at least one processor, cause the computing platform to determine the center of gravity for the retrieved partition based on the geometry data of BIM data objects of the retrieved partition.

16. The non-transitory computer-readable medium of claim 13, wherein the geometry data for a given BIM data object of the plurality of BIM data objects comprises: (i) a number of vertices of the given BIM data object and (ii) a number of triangular faces of the given BIM data object.

17. The non-transitory computer-readable medium of claim 13:
wherein the program instructions that, when executed by at least one processor, cause the computing platform to access the set of information comprise program instructions that, when executed by at least one processor, cause the computing platform to access the set of information from a given BIM file; and
wherein the non-transitory computer-readable medium is also provisioned with program instructions that, when executed by at least one processor, cause the computing platform to determine that the set of information accessed from the given BIM file exceeds a threshold size.

18. The non-transitory computer-readable medium of claim 17, wherein the program instructions that, when executed by at least one processor, cause the computing platform to add the partition for the given BIM model to the set of partitions comprise program instructions that, when executed by at least one processor, cause the computing platform to add the partition for the given BIM model to the set of partitions based on determining that the set of information accessed from the given BIM file exceeds the threshold size.

19. The non-transitory computer-readable medium of claim 13, wherein the non-transitory computer-readable medium is also provisioned with program instructions that, when executed by at least one processor, cause the computing platform to:
transmit the generated partitions index file to a client device for use in rendering the given BIM model.

20. A method implemented by a computing platform, the method comprising:
accessing a set of information encoding geometry data for a plurality of building information model (BIM) data objects for a given BIM model;
adding a partition for the given BIM model to a set of partitions, wherein the partition for the given BIM model comprises the plurality of BIM data objects;
for each partition of one or more partitions that each satisfies a partition size threshold, generating a respective partition file by, while the set of partitions includes a partition that does not satisfy the partition size threshold:
retrieving a partition from the set of partitions;
determining whether the retrieved partition satisfies the partition size threshold;
based on determining that the retrieved partition does not satisfy the partition size threshold, (i) determining a center of gravity for the retrieved partition, (ii) splitting the retrieved partition into (a) a first partition that falls to a first side of the determined center of gravity for the retrieved partition and (b) a second partition that falls to a second side of the determined center of gravity for the retrieved partition, and (iii) adding the first partition and the second partition to the set of partitions; and
based on determining that the retrieved partition satisfies the partition size threshold, generating a partition file for the retrieved partition; and
generating a partitions index file mapping each BIM data object of the plurality of BIM data objects to a corresponding generated partition file.
